(19) United States
(12) Patent Application Publication
(10) Pub. No.: US 2009/0051428 A1
(43) Pub. Date: Feb. 26, 2009

(54) AGC CIRCUIT

(75) Inventors: Keiji AMEMIYA, Saitama (JP); Hidekazu INOUE, Gunma (JP)

Correspondence Address: MORRISON & FOERSTER LLP, 1650 TYSONS BOULEVARD, SUITE 400, MCLEAN, VA, 22102, US

(73) Assignees: Sanyo Electric Co., Ltd., Moriguchi-shi (JP); Sanyo Semiconductor Co., Ltd., Ora-gun (JP)

(21) Appl. No.: 11/926,840

(22) Filed: Oct. 29, 2007

(30) Foreign Application Priority Data
Aug. 23, 2007 (JP) 2007-217425

(51) Int. Cl. H03F 3/45

(52) U.S. Cl. 330/254

(57) ABSTRACT

This invention offers an AGC circuit that prevents disturbance in an output waveform when an input signal varies abruptly. A first terminal of a capacitor is connected with an output terminal of a variable gain amplifier and a second terminal of the capacitor is connected with a non-inverting input terminal (+) of a differential amplifier. A reference voltage Vref2 is applied to an inverting input terminal (−) of the differential amplifier. A bias voltage Vbias from a bias circuit is applied to the non-inverting input terminal (+) of the differential amplifier, while the reference voltage Vref2 from the bias circuit is applied to the inverting input terminal (−) of the differential amplifier. An output signal of the differential amplifier is applied to the variable gain amplifier through a direct current amplifier as a direct current control voltage.

### CROSS-REFERENCE OF THE INVENTION

This application claims priority from Japanese Patent Application No. 2007-217425, the content of which is incorporated herein by reference in its entirety.

### BACKGROUND OF THE INVENTION

1. Field of the Invention

This invention relates to an AGC (Automatic Gain Control) circuit.

2. Description of the Related Art

The AGC circuit controls a gain of a variable gain amplifier so that amplitude of an audio signal, a video signal or the like becomes a predetermined value. FIG. 3 shows a structure of a conventional AGC circuit.

An analog input signal applied to an input terminal 1 is amplified by a variable gain amplifier 2 and thereafter outputted from an output terminal 4 through an attenuator 3. A gain of the variable gain amplifier 2 is controlled by a direct current control voltage generated based on amplitude of an output signal of the variable gain amplifier 2. A control circuit that generates the direct current control voltage is formed using a clamp circuit as described below.

A first terminal of a capacitor 5 is connected with an output terminal of the variable gain amplifier 2, and a second terminal of the capacitor 5 is connected with a non-inverting input terminal (+) of a differential amplifier 6. A reference voltage Vref1 is applied to an inverting input terminal (−) of the differential amplifier 6. An emitter of an NPN transistor 7 is connected with the non-inverting input terminal (+) of the differential amplifier 6, while an emitter of an NPN transistor 8 is connected with the inverting input terminal (−) of the differential amplifier 6. A base voltage is applied from a common voltage source 9 to a base of each of the NPN transistors 7 and 8. An output of the differential amplifier 6 is applied to the variable gain amplifier 2 through a direct current amplifier 10 as a direct current control voltage. A smoothing capacitor 12 is connected with an output terminal of the differential amplifier 6 through a terminal 11.

Next, an operation of the circuit will be explained referring to FIG. 4. The output signal of the variable gain amplifier 2 is applied to the non-inverting input terminal (+) of the differential amplifier 6 through the capacitor 5. When the amplitude of the output signal of the variable gain amplifier 2 varies as the input signal varies, clamping operation is performed so that a minimum value of the output signal is aligned to a clamp level. The clamping level is set equal to the reference voltage Vref1.

As a result, the differential amplifier 6 generates a voltage corresponding to a difference between the output signal and the reference voltage Vref1. When the amplitude of the output signal increases, the voltage increases and the direct current control voltage increases as well. Thus, the gain of the variable gain amplifier 2 is controlled to decrease. Also, when the amplitude of the output signal decreases, the voltage decreases and the direct current control voltage decreases as well. Thus, the gain of the variable gain amplifier 2 is controlled to increase. Therefore, it is made possible with the AGC circuit described above that the gain of the variable gain amplifier 2 is controlled so that the amplitude of the output signal becomes a predetermined value.

Further description on the AGC circuit is found in Japanese Patent Application Publication No. 2003-198875, for example.

With the conventional AGC circuit however, there has been a problem that the output waveform is disturbed and it takes considerably long time before it is settled when the input signal varies abruptly, as shown in FIG. 5. This is because a delay time required to complete the clamping operation of the clamp circuit is long as shown in FIG. 4, since the conventional circuit uses the clamp circuit.

### SUMMARY OF THE INVENTION

This invention offers an AGC circuit having a variable gain amplifier, a gain of which is variably controlled in response to a control voltage and a control circuit that generates the control voltage in response to an output signal of the variable gain amplifier, the control circuit including a capacitor having a first terminal connected with an output terminal of the variable gain amplifier and a second terminal, a differential amplifier having a first input terminal connected with the second terminal of the capacitor and a second input terminal, and a bias circuit that biases the first input terminal at a first voltage and the second input terminal at a second voltage, wherein the first and second voltages are set between a maximum value and a minimum value of the output signal of the variable gain amplifier.

### BRIEF DESCRIPTION OF THE DRAWINGS

FIG. 1 shows a structure of an AGC circuit according to an embodiment of this invention.

FIG. 2 is a waveform chart showing an operation of the AGC circuit according to the embodiment of this invention.

FIG. 3 shows a structure of a conventional AGC circuit.

FIG. 4 is a waveform chart showing an operation of the conventional AGC circuit.

FIG. 5 is a waveform chart showing transient response characteristics of the conventional AGC circuit.

FIG. 6 is a waveform chart showing transient response characteristics of the AGC circuit according to the embodiment of this invention.

### DETAILED DESCRIPTION OF THE INVENTION

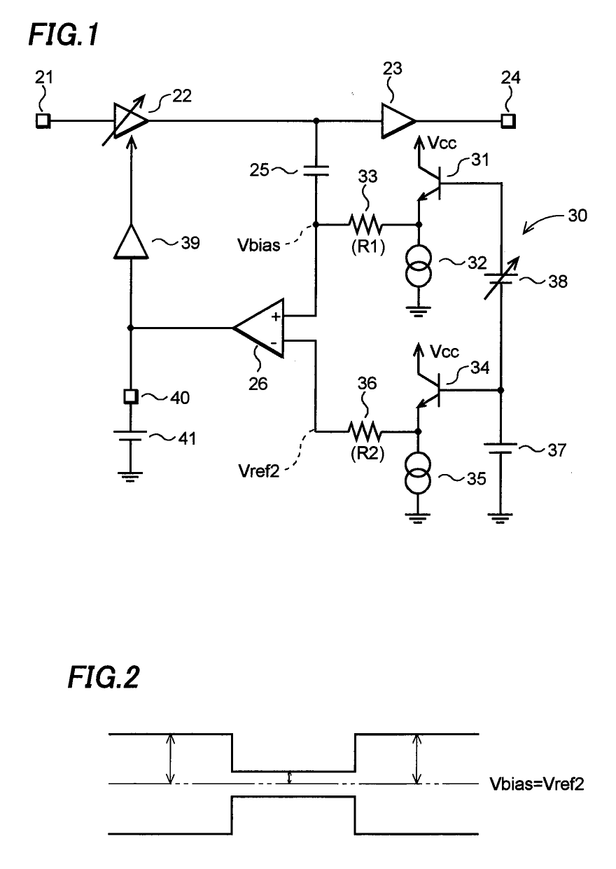

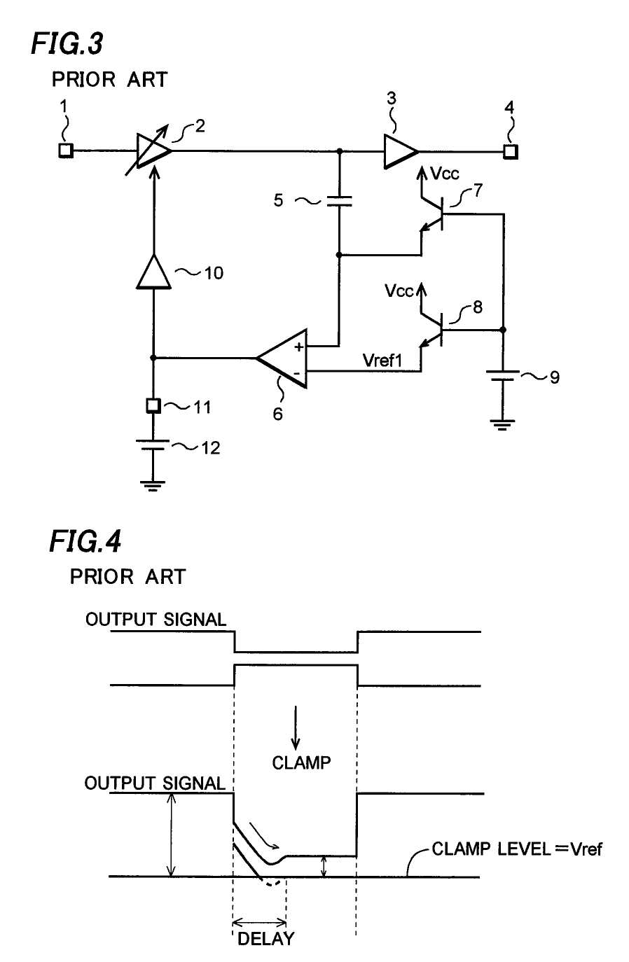

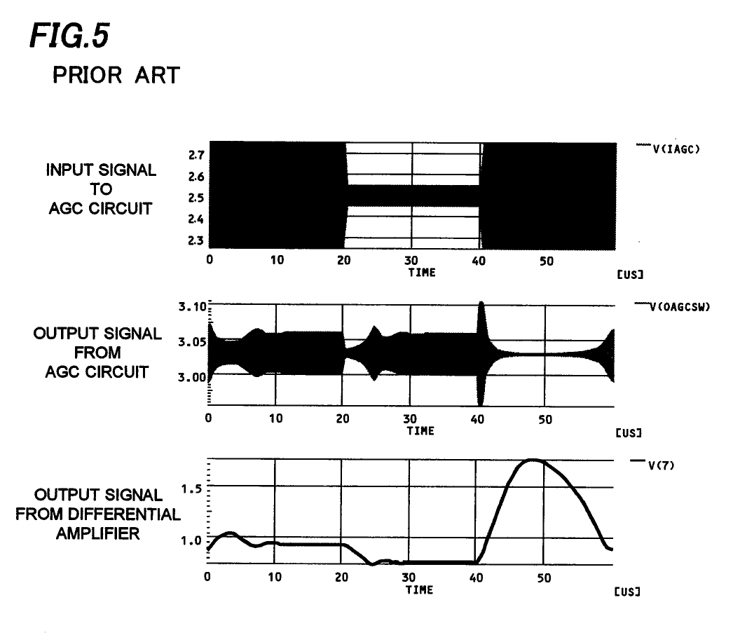

An AGC circuit according to an embodiment of this invention is described hereafter. FIG. 1 shows a structure of the AGC circuit. An analog input signal applied to an input terminal 21 is amplified by a variable gain amplifier 22 and thereafter outputted from an output terminal 24 through an attenuator 23. A gain of the variable gain amplifier 22 is controlled by a direct current control voltage generated based on amplitude of an output signal of the variable gain amplifier 22. In the AGC circuit according to the embodiment of this invention, a control circuit that generates the direct current control voltage is formed using a bias circuit 30 so that transient response characteristics of the AGC circuit are improved.

A first terminal of a capacitor 25 is connected with an output terminal of the variable gain amplifier 22, and a second terminal of the capacitor 25 is connected with a non-inverting input terminal (+) of a differential amplifier 26. A reference voltage Vref2 is applied to an inverting input terminal (−) of the differential amplifier 26.

A bias voltage Vbias from the bias circuit 30 is applied to the non-inverting input terminal (+) of the differential amplifier 26, while the reference voltage Vref2 from the bias circuit 30 is applied to the inverting input terminal (−) of the differential amplifier 26.

The bias circuit 30 is provided with a first NPN transistor 31, a first constant current source 32 connected with an emitter of the first transistor 31 and a first resistor 33 connected between the emitter of the first transistor 31 and the non-inverting input terminal (+) of the differential amplifier 26. The bias voltage Vbias is outputted from the emitter of the first transistor 31.

The bias circuit 30 is also provided with a second NPN transistor 34, a second constant current source 35 connected with an emitter of the second transistor 34 and a second resistor 36 connected between the emitter of the second transistor 34 and the inverting input terminal (−) of the differential amplifier 26. The reference voltage Vref2 is outputted from the emitter of the second transistor 34.

A power supply voltage Vcc is applied to both collectors of the first transistor 31 and the second transistor 34. A voltage from a first voltage source 37 is applied to a base of the second transistor 34. A voltage from a second voltage source 38 that is connected in series with the first voltage source 37 is applied to a base of the first transistor 31. The second voltage source 38 is a variable voltage source. Therefore, a voltage that is a sum of the voltage from the first voltage source 37 and the voltage from the second voltage source 38 is applied to the base of the first transistor 31.

The bias voltage Vbias and the reference voltage Vref2 can be varied by adjusting circuit constants. The bias voltage Vbias and the reference voltage Vref2 are set between a maximum value and a minimum value of the amplitude of the output signal of the variable gain amplifier 22 that is applied to the non-inverting input terminal (+) of the differential amplifier 26 through the capacitor 25.

The bias voltage Vbias can be made equal to the reference voltage Vref2 (Vbias=Vref2) by setting a resistance R1 of the first resistor 33 equal to a resistance R2 of the second resistor 36, setting an electric current I1 of the first constant current source 32 equal to an electric current 12 of the second constant current source 35 and setting the voltage from the second voltage source 38 equal to zero. An output signal of the differential amplifier 26 is applied to the variable gain amplifier 22 through a direct current amplifier 39 as the direct current control voltage. A smoothing capacitor 41 is connected with an output terminal of the differential amplifier 26 through a terminal 40.

With the AGC circuit described above, the differential amplifier 26 generates a voltage corresponding to a difference between the output signal and the reference voltage Vref2. When the amplitude of the output signal increases, the voltage increases and the direct current control voltage increases as well. Thus, the gain of the variable gain amplifier 22 is controlled to decrease. Also, when the amplitude of the output signal decreases, the voltage decreases and the direct current control voltage decreases as well. Thus, the gain of the variable gain amplifier 22 is controlled to increase. Therefore, it is made possible with the AGC circuit described above that the gain of the variable gain amplifier 22 is controlled so that the amplitude of the output signal becomes a predetermined value.

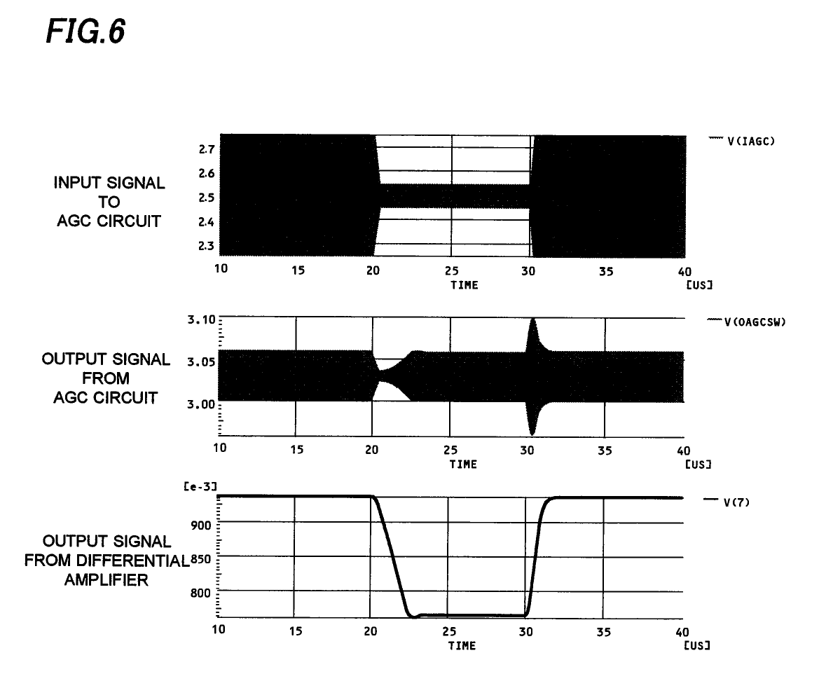

Even when the input signal varies abruptly, it is made possible that the output signal quickly follows the change in the input signal to prevent the disturbance in the output waveform, as shown in FIG. 6. This is because the amplitude of the output signal can be detected in real time without the long delay caused in the case where the clamp circuit is used, since the bias voltage Vbias and the reference voltage Vref2 are set between the maximum value and the minimum value of the amplitude of the output signal of the variable gain amplifier 22 that is applied to the non-inverting input terminal (+) of the differential amplifier 26 through the capacitor 25, as shown in FIG. 2.

It is preferable in order to detect the amplitude of the output signal precisely in real time that the bias voltage Vbias is set equal to the reference voltage Vref2. It is more preferable that the bias voltage Vbias and the reference voltage Vref2 are set at a center of the maximum value and the minimum value of the amplitude of the output signal of the variable gain amplifier 22 that is applied to the non-inverting input terminal (+) of the differential amplifier 26.

This invention is not limited to the embodiment described above and may be modified within the scope of the invention. For example, the bias voltage Vbias may be set equal to the reference voltage Vref2 by removing the second voltage source 38 and thereby applying the same voltage from the first voltage source 37 to both the base of the first transistor 31 and the base of the second transistor 34.

With the AGC circuit according to the embodiment of this invention, the amplitude of the output signal can be detected in real time, since the bias circuit is used as the control circuit of the variable gain amplifier instead of the clamp circuit. As a result, it is made possible that the output signal quickly follows the change in the input signal to prevent the disturbance in the output waveform, even when the input signal varies abruptly.

What is claimed is:

1. An automatic gain control circuit comprising:
a variable gain amplifier changing a gain in response to a control voltage and outputting an output signal from an output terminal; and
a control circuit generating the control voltage in response to the output signal and comprising a capacitor comprising a first terminal and a second terminal, a differential amplifier comprising a first input terminal and a second input terminal and a bias circuit biasing the first input terminal at a first voltage and the second input terminal at a second voltage,
wherein the first terminal of the capacitor is connected to the output terminal of the variable gain amplifier, the second terminal of the capacitor is connected to the first input terminal of the differential amplifier, and
the first and second voltages are set between a maximum value and a minimum value of the output signal of the variable gain amplifier.

2. The circuit of claim 1, wherein the first voltage is equal to the second voltage.

3. The circuit of claim 2, wherein the first voltage and the second voltage are set at a center of the maximum value and the minimum value of the output signal of the variable gain amplifier.

4. The circuit of claim 1, wherein the bias circuit comprises a first transistor, a first constant current source connected to an emitter of the first transistor, a first resistor connected between the emitter of the first transistor and the first input terminal, a second transistor, a second constant current source connected to an emitter of the second transistor and a second resistor connected between the emitter of the second transistor and the second input terminal.

5. The circuit of claim 4, wherein a resistance of the first resistor is equal to a resistance of the second resistor, and an electric current of the first constant current source is equal to an electric current of the second constant current source.
